(19) United States
(12) Patent Application Publication
(10) Pub. No.: US 2012/0078547 A1
(43) Pub. Date: Mar. 29, 2012

(54) INTERNET BASED ENERGY CONTROL SYSTEM

(75) Inventor: John Bruce Murdoch, Wind Gap, PA (US)

(73) Assignee: LUTRON ELECTRONICS CO., INC., Coopersburg, PA (US)

(21) Appl. No.: 12/891,372

(22) Filed: Sep. 27, 2010

(51) Int. Cl. G01R 21/00; G06F 19/00

(52) U.S. Cl. 702/62

(57) ABSTRACT

A system and method for providing power usage information by an electric power meter. The meter measures and reports power usage of at least one of a plurality of electrical loads connected into an electrical power network, wherein the electric power meter is synchronized to measure power usage at a particular time, and is further configured and operable to communicate over a first data network that is communicatively coupled to a second data network, and further wherein at least one firewall is positioned between the first and second data networks.

### BACKGROUND OF THE INVENTION

1. Field of the Invention

The present invention relates, generally, to energy usage and savings and, more particularly, to configuring and using an energy meter to report energy usage over a communication network.

2. Description of the Related Art

The world's awareness of a correlation between energy consumption and power usage with environmental concerns, including those related to global warming and pollution, continues to increase. Referred to, generally, as the “Green Revolution,” this awareness is becoming particularly acute in spaces in which people live and work, as lighting and other power usage control solutions that save energy and enhance those spaces are increasing demand. In addition to homes, apartment complexes and business locations, a demand for such power usage and energy consumption control devices in schools has risen, particularly as children and young adults are educated in environmental and ecological concerns and conditions.

Currently, energy meters, including electric power meters, measure power that is used by one or more devices. Utilizing information representing measured power usage would be useful for increasing such environmental awareness, as well as to enable users to control energy usage and savings.

### SUMMARY OF THE INVENTION

In an embodiment, power usage information is provided by an electric power meter that measures and reports power usage of at least one of a plurality of electrical loads connected into an electrical power network. The electric power meter is synchronized to measure power usage at a particular time, and is further configured and operable to communicate over a first data network that is communicatively coupled to a second data network. At least one firewall is positioned between the first and second data networks. A real time clock is provided with the electric power meter, and is synchronized with a first computing device that is provided with an accurate timestamp from outside the firewall. The electric power meter reads an amount of power used by the at least one load at a particular point in time, and transmits usage information that represents the amount of electricity used by the at least one load device at the particular point in time. The particular point in time is accurately represented as a function of the synchronized real time clock.

In an embodiment, a message is sent by the electric power meter to the first computing device. The electric power meter records first time information from the real time clock that represents a first time when the message is transmitted to the first computing device. A response to the message is received from the first computing device that includes second time information representing a second time when the response to the message was transmitted from the first computing device to the electric power meter. The electric power meter records third time information from the real time clock, wherein the third time information represents a third time when the response to the message is received by the electric power meter. The electric power meter subtracts the first time from the third time to determine a first calculated amount of time that represents an amount of time from when the message was sent from the electric power meter to when the response was received by the electric power meter. The electric power meter divides the first calculated amount of time in half to determine a second calculated amount of time representing a transit time between the electric power meter and the first computing device. The electric power meter adds the second calculated amount of time to the first time to calculate a fourth time, and compares the fourth time to the second time and synchronizes the real time clock based on the comparing.

In another embodiment, software is updated that executes on an electric power meter that measures and reports power usage of at least one of a plurality of electrical loads connected into an electrical power network. The electric power meter is synchronized to measure power usage at a particular time, and is further configured and operable to communicate over a first data network that is communicatively coupled to a second data network, and further wherein at least one firewall is positioned between the first and second data networks. The electric power meter transmits a first request to a first computing device, wherein the request relates to whether a software update is due. The electric power meter receives a first response to the first request from the first computing device, wherein the first response includes at least one detail for updating the software. The software is updated as a function of the at least one detail.

In an embodiment, the first request includes at least a first version identification that represents a version of the software that is installed on the electric power meter. Further, the at least one detail includes a second version identification of the software that represents another version of the software to be updated on the electric power meter. Yet further, the at least one detail includes a time for the electric power meter to download and update the software.

In an embodiment, the electric power meter transmits a second request to the first computing device for at least one data packet substantially at the time included in the at least one detail. The electric power meter receives from the first computing device and in response to the second request, the at least one data packet. The electric power meter transmits a third request for at least one additional data packet and receives from the first computing device and in response to the third request, the at least one additional data packet. The steps of transmitting the third request and the receiving the at least one additional data packet is are repeated until the software update is fully received by the electric power meter, and the updated software is installed in accordance with the at least one detail.

In another embodiment, an electric power meter that measures and reports power usage of at least one of a plurality of electrical loads connected into an electrical power network is configured. The electric power meter is synchronized to measure power usage at a particular time, and is further configured and operable to communicate over a first data network that is communicatively coupled to a second data network. At least one firewall is positioned between the first and second data networks. A graphical user interface is provided by a first computing device over the second data network, wherein the graphical user interface provides controls for a user to configure the electric power meter to measure power usage at the particular time, and further to configure the electric power meter to request a software upgrade at predetermined time intervals.

Other features and advantages of the present invention will become apparent from the following description of the invention that refers to the accompanying drawings.

### BRIEF DESCRIPTION OF THE DRAWINGS

FIG. 1 is a simplified block diagram of an energy metering system according to an embodiment;

FIG. 2 is an example login web page display screen provided on a client computing device for accessing a web-based lighting control, in accordance with an embodiment;

FIGS. 3-8 illustrate example web browser display screens useable for configuring an energy meter according to an embodiment;

FIG. 9 is an example web browser display screen for testing communications with an energy meter in accordance with an embodiment;

FIG. 10 is an example output table that is displayed in response to a user executing a data communication test;

FIGS. 11-13 are flowcharts showing example steps associated with updating firmware for an energy meter, in accordance with an embodiment; and

FIG. 14 is a flowchart illustrating example steps associated with synchronizing an energy meter real time clock in accordance with an embodiment.

### DETAILED DESCRIPTION OF THE INVENTION

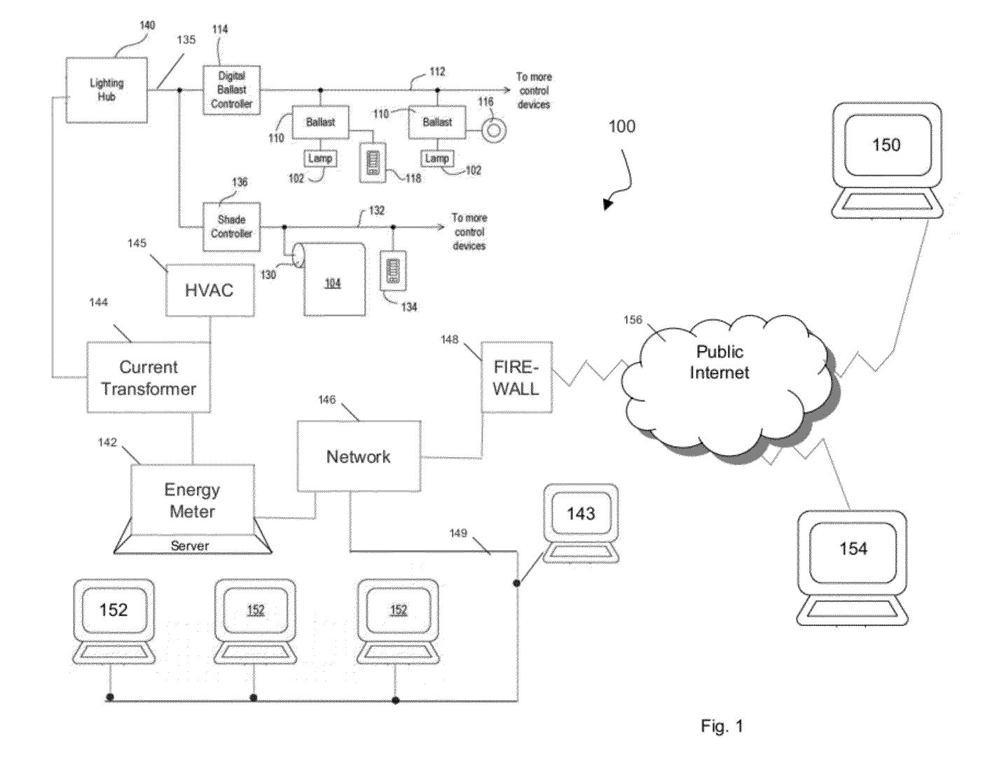

An example hardware arrangement including a plurality of devices configured to transmit and receive information over a network according to an embodiment is shown in FIG. 1, and referred generally herein as energy metering system 100. As used herein, the term, “energy,” refers generally to power over a period of time. Energy metering system 100 is operable to measure energy consumption and/or power usage in a facility, such as a school, and to send and receive digital messages related thereto between devices configured to communicate on the system. Preferably, current and up-to-the-minute information representing power usage and/or savings is provided for a user to control, for example, levels of illumination in one or more spaces of a building. In an example hardware arrangement, such as shown in FIG. 1 which includes a lighting control system having electronic window shade controllers, the intensity level of the electrical lights in the space(s) can be controlled as a function of controlling positions of shades to allow or prevent daylight from entering the space(s) (referred to herein, generally, as “daylighting”). Energy metering system 100 may be configured and operable to report the amount of power delivered to (e.g., the intensity of) a plurality of lighting loads, e.g., a plurality of fluorescent lamps 102. Energy metering system 100 may be further configured and operable to control and report the position of a plurality of motorized window treatments, e.g., motorized roller shades 104, as a function of the amount of power delivered to the lighting loads, as well as to control the amount of daylight entering the space. Examples of such lighting control systems are described in greater detail in commonly-assigned U.S. Pat. No. 6,803,728, issued Oct. 12, 2004, entitled SYSTEM FOR CONTROL OF DEVICES, and U.S. patent application Ser. No. 11/870,783, filed Oct. 11, 2007, entitled METHOD OF BUILDING A DATABASE OF A LIGHTING CONTROL SYSTEM, each of which is incorporated herein by reference in its entirety.

Continuing with reference to FIG. 1, fluorescent lamps 102 may be coupled to one of a plurality of lighting control devices, such as digital electronic dimming ballasts 110, for control of the intensities of the lamps. The ballasts 110 are operable to communicate with each other via a digital ballast communication link 112. For example, the digital ballast communication link 112 may comprise a digital addressable lighting interface (DALI) communication link. The digital ballast communication link 112 is also coupled to a digital ballast controller (DBC) 114, which provides the necessary direct-current (DC) voltage to a power communication link 112 and assists in the programming of energy metering system 100. Each of the ballasts 110 is operable to receive inputs from a plurality of sources, for example, an occupancy or vacancy sensor 116, a daylight sensor (not shown), an infrared (IR) receiver (not shown), or a keypad device 118. The occupancy sensors 116 may be mounted to detect the presence of an occupant (e.g., either an occupancy condition or a vacancy condition) in one or more of the workspace areas of the building. The ballasts 110 may be operable to transmit digital messages to other ballasts 110 in response to the inputs received from the various sources. An example of a digital electronic dimming ballast operable to be coupled to a communication link and a plurality of other input sources is described in greater detail in commonly-assigned U.S. Pat. No. 7,619,539, filed Apr. 14, 2004, entitled MULTIPLE-INPUT ELECTRONIC BALLAST WITH PROCESSOR, and U.S. Pat. No. 7,369,060, filed Dec. 14, 2004, entitled DISTRIBUTED INTELLIGENCE BALLAST SYSTEM AND EXTENDED LIGHTING CONTROL PROTOCOL. The entire disclosures of both applications are hereby incorporated by reference.

In the example shown in FIG. 1, each of the motorized roller shades 104 comprises an electronic drive unit 130. Each electronic drive unit 130 is preferably located inside the roller tube of the associated roller shade 104. The electronic drive units 130 are responsive to digital messages received, such as from a keypad device 134 via a shade communication link 132. The user is operable to open or close the motorized roller shades 104, adjust the position of the shade fabric of the roller shades, or set the roller shades to preset shade positions in response to messages received from a user. An example of a motorized window treatment control system is described in greater detail in commonly-assigned U.S. Pat. No. 6,983,783, issued Jun. 11, 2006, entitled MOTORIZED SHADE CONTROL SYSTEM, and U.S. Pat. No. 7,111,952, issued Sep. 26, 2006, entitled SYSTEM TO CONTROL DAYLIGHT AND ARTIFICIAL ILLUMINATION AND SUN GLARE IN A SPACE. The entire disclosures of both patents are hereby incorporated by reference.

Continuing with the simplified block diagram shown in FIG. 1, energy metering system 100 further includes a central controller, such as a lighting hub 140, for controlling the ballasts 110 and the motorized roller shades 104. In the example shown in FIG. 1, a lighting hub 140 is coupled to a digital ballast controller 114, which is coupled to ballasts 110 on a digital ballast communication link 112. The lighting hub 140 may further be coupled to a shade controller 136, which is coupled to motorized roller shades 104 on shade communication link 132. The lighting hub 140 may further be coupled to additional lighting hubs via interprocessor link 135 (e.g., an Ethernet link) such as to allow additional digital ballast controllers 114 and shade controllers 136 to be included in energy metering system 100. Examples of the lighting hub 140 and the interprocessor link 135 are described in greater detail in U.S. patent application Ser. No. 11/938,039, filed Nov. 9, 2007, entitled INTERPROCESSOR COMMUNICATION LINK FOR A LOAD CONTROL SYSTEM, the entire disclosure of which is hereby incorporated by reference.

Moreover, a plurality of electrical loads may be controlled in response to a total amount of power presently being consumed by the plurality of loads, and as reported by an energy meter 142. One or more load shed commands may be issued, accordingly, which results in a lowering of the amount of electricity used by the plurality of loads. Examples of systems and methods for load shedding are described in greater detail in U.S. patent application Ser. No. 11/398,604, filed Nov. 12, 2007, entitled METHOD OF COMMUNICATING A COMMAND FOR LOAD SHEDDING OF A LOAD CONTROL SYSTEM, the entire disclosure of which is hereby incorporated by reference.

In the embodiment shown in example hardware arrangement of FIG. 1, the energy meter 142 is coupled to a current transformer 144 and configured to measure power usage, such as delivered to devices installed via the lighting hub 140 and/or heating, ventilation and cooling (“HVAC”) system 145. The energy meter 142 is preferably also configured to communicate with one or more devices and to send and receive digital messages over network 146 that are related thereto. The energy meter 142 according to the teachings herein measures energy consumed and/or power used in a facility, such as a school, business, residential building or other location. The energy meter 142 is further operable to indicate an amount of energy that is being used and/or saved at a particular time or over a period of time, and in preferred embodiments, a digital addressable lighting control system is used that is controllable and operable for improved energy savings. According to the teachings herein, the energy meter 142 measures energy consumption that can be used, for example, to compare a facility's lighting control system to switched lighting systems that use standard prior art ballasts, to compare power usage in one location in a facility to that of another, as well as for numerous data-related analyses in connection with energy and power usage and savings.

Energy metering system 100 may further include a proxy server computing device 143, which may be coupled to the intranet network 146 (e.g., an Ethernet link) via an interprocessor link 149 behind firewall 148, and that supports much of the functionality described herein, and project server computing device 150 which is preferably coupled to Public Internet 156 and outside firewall 148. By providing the project server computing device 150 outside the firewall 148 and on the public Internet 156, a plurality of energy meters 142 can be managed and/or configured in accordance with the teachings herein.

Interprocessor link 149 is preferably coupled to Intranet network 146 that enables computing devices 152 to send/receive digital messages to/from the project server computing device 150 and/or energy meter 142, thereby allowing for communication between the various computing devices 142, 143, 150, 152 and the various load control devices, e.g., ballasts 110 and electronic drive units 130 of the energy metering system 100. In various embodiments, any of project server computing device 150, computing devices 152 and/or energy meter 142 may be configured and/or operable as a hypertext transport protocol (“HTTP”) web server, thereby providing remote access thereto via standard web browsing software applications. Accordingly, the devices are preferably configured with one or more of a processor, processor readable media, and a communications module. Computing devices 143, 150, and/or 152 may be further provided in various other “host” configurations, such as to provide server-side processing, e.g., servlets, active server pages, personal home page (“PHP”) processing, flash processing, database management and/or other back-end processes to support the functionality in accordance with the teachings herein. Moreover, each of computing devices 150, 152 may be configured with a web browser software application, thereby enabling the devices to operate as web clients, as well.

In various embodiments, the energy meter 142, project server computing device 150 and client computing devices 152 may be any devices that are capable of sending and receiving data across network 146, e.g., mainframe computers, mini computers, personal computers, laptop computers, a personal digital assistants (PDA) and Internet access devices such as Web TV. In addition, project server computing device 150 and client computing devices 152 are preferably equipped with a web browser, such as MICROSOFT INTERNET EXPLORER, MOZILLA FIREFOX and the like. The energy meter 142, the project server computing device 150 and the client computing devices 152 are coupled to network 146 using any known data communication networking technology.

Preferably, the project server computing device 150 includes a project server graphical user interface that, when accessed, enables a user to manage configurations associated with energy metering system 100. When executed in web browser software, for example, operated on the client computing device 152, the administration graphical user interface includes one or more graphical screen controls for the user to configure and monitor the operation of the energy metering system 100. For example, a user operating the project server graphical user interface can interrogate the energy meter 142, such as to determine the amount of power used and/or saved as a function of the operation of ballasts 110, digital ballast controllers 114, electronic drive units 130, shade controllers 136, and/or lighting hubs 140 that are connected and/or active.

The project server computing device 150 may be configured and operable to transmit an alert to the user in response to a detected condition. For example, a signal is transmitted over link 149 that power usage and/or energy consumption has exceeded a predefined threshold, and may further include one or more spaces where that condition has occurred. In response to the signal, an alert representing the condition is generated and sent by the project server computing device 150 to the client computing device 152. The project server computing device 150 may be configured to send the alert as an e-mail message. Alternatively, the project server computing device 150 may print an alert page on a printer, and/or may display an alert screen on the project server computing device 150 and/or the client computing device 152 to alert a user to a condition.

In an embodiment, energy metering system 100 includes a visual display that provides a visual indication of energy savings and energy usage information. The visual display is preferably provided via the project server computing device 150 and/or the client computing devices 152, and represents energy savings and energy usage data in one or more spaces. An example of a visual display is described in greater detail in U.S. patent application Ser. No. 12/044,672, filed Mar. 7, 2008, entitled SYSTEM AND METHOD FOR GRAPHICALLY DISPLAYING ENERGY CONSUMPTION AND SAVINGS, the entire disclosure of which is hereby incorporated by reference. In yet another alternative embodiment, the visual indication is incorporated into one or more other display screens for controlling electrical loads in energy metering system 100, such as described herein.

According to an embodiment, a graphical user interface is provided for a user to configure the energy meter 142, for example, using the project server computing device 150. In one embodiment, the graphical user interface operates within a web browser software application running on the project server computing device 150. Alternatively, the interface is operable and configured to run “locally” on the client computing device 152, such as in the form of an applet that is downloaded from the project server computing device 150 when the client computing device 152 connects thereto. In this alternative embodiment, the interface may be provided and, in response, user commands may be issued in the applet or other locally provided program. Graphical screen controls are preferably displayed in the interface that are selected and/or activated by a user. In one embodiment, the commands are transmitted to the energy meter 142, such as during a communication session therewith, and are used by the energy meter 142 to configure communication settings, including internet addressing information for the energy meter 142, project server computing device 150 communication settings, reporting configuration and options, date and time settings, or the like. Once configured, information representing the power usage, including via the lighting loads 102, the HVAC system 145 and/or other electrical devices may further be transmitted to the project server 150, which may update information in an applet or other local program running on the client computing device 152 to provide a visual indication of power usage and/or energy consumption.

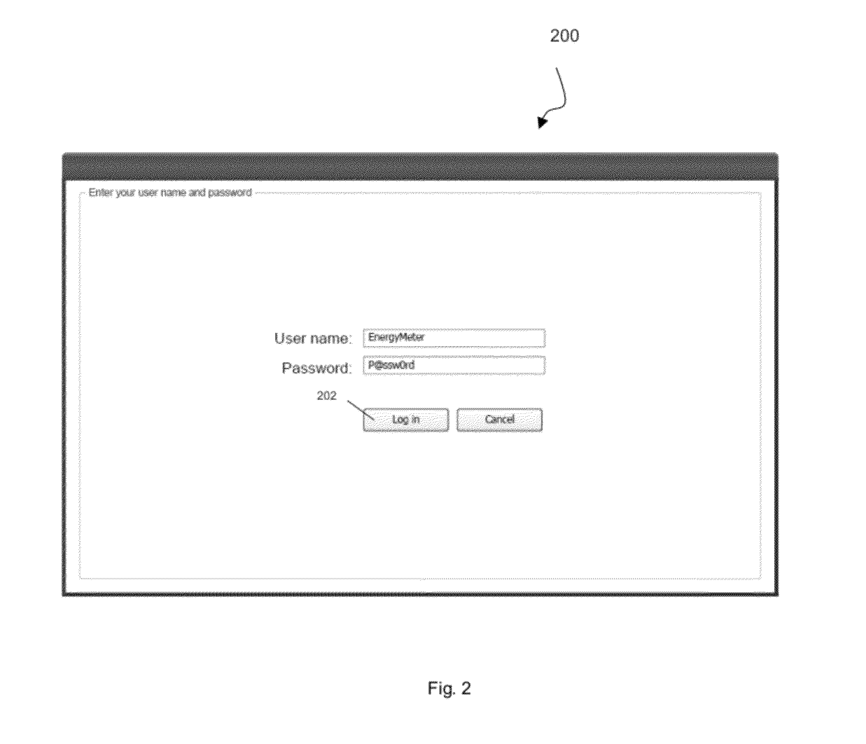

Referring now to FIGS. 2-9, example display screens and corresponding descriptions of the energy meter 142 are provided. Beginning with the example display screen 200 shown in FIG. 2, a user establishes a data communication session for referencing and/or configuring the energy meter 142 via standard Internet web browsing software, such as MICROSOF INTERNET EXPLORER, MOZILLA FIREFOX, or any other HTML/W3C compliant browser. Prior to enabling a user to reference or configure the energy meter 142, the user is directed to a default page 200 and the user is prompted to enter authorization information, such as a user name and password. In an embodiment, user authorization information is provided with the energy meter 142, such as by being hard-coded into the energy meter 142 firmware, and referenced each time a user attempts to access the meter 142, thereby precluding unauthorized access. In alternative embodiments, user authorization information is stored on a server, such as project server computing device 150, and referenced each time a user attempts to access the meter 142.

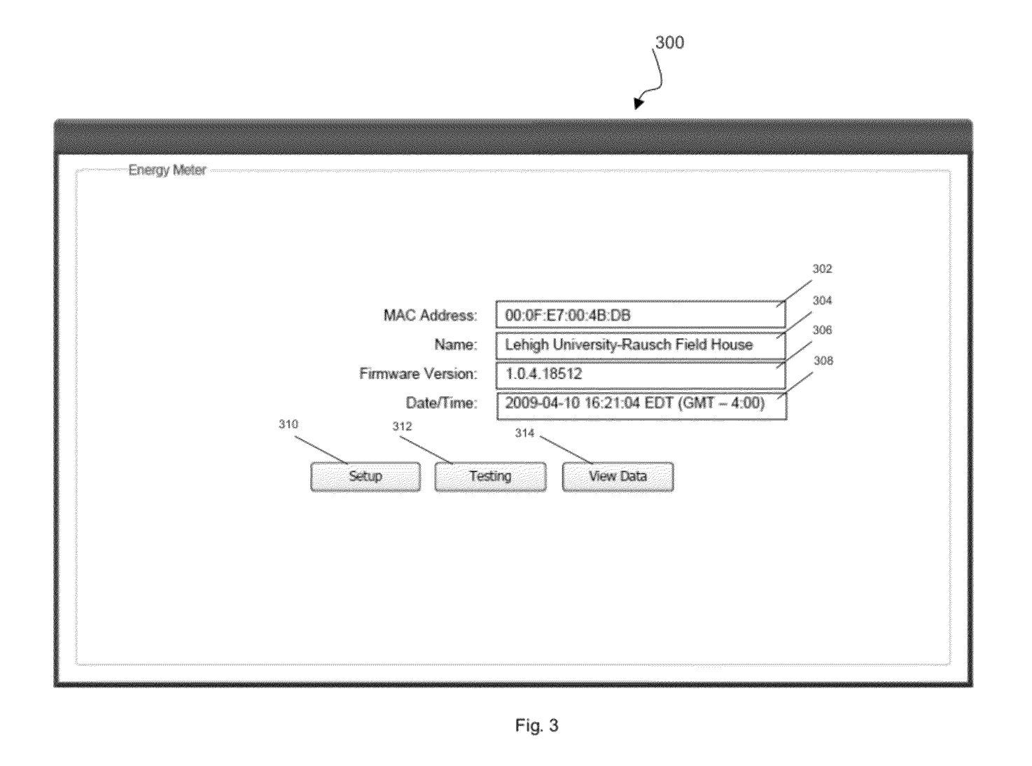

Continuing with reference to FIG. 2, after the user submits proper authorization information, the user selects a graphical screen control, such as Log in button 202 and the user's browser is passed a cookie, as known in the art, that includes a unique identifier of a user session (i.e., a session identifier). The energy meter 142 is operable to store the session identifier along with an expiration date and time (e.g., the current date and a calculated time that represents the current time plus 20 minutes.) Once the cookie is passed, the user's browser software is redirected to display screen 300, such as shown in FIG. 3. In the event that the user submits authorization information that is not recognized or is otherwise insufficient to access the energy meter 142, then the user's web browser software application is preferably directed back to the default page so that the user can re-enter his/her authorization information. Preferably, each time the user attempts to re-establish a connection to the energy meter 142, the expiration date and time corresponding to the session identifier is verified by the energy meter. If the expiration date and time has been reached (i.e., the current time is later than the expiration time), then the user's browser is redirected to the energy meter's 142 default login web page 200. Alternatively, if the expiration day and time has not been reached, then the expiration date and time corresponding to the session identifier is modified to be 20 minutes from the present time. Thus in accordance with this embodiment, a user who leaves the browser open with no activity for 20 minutes will time out the session.

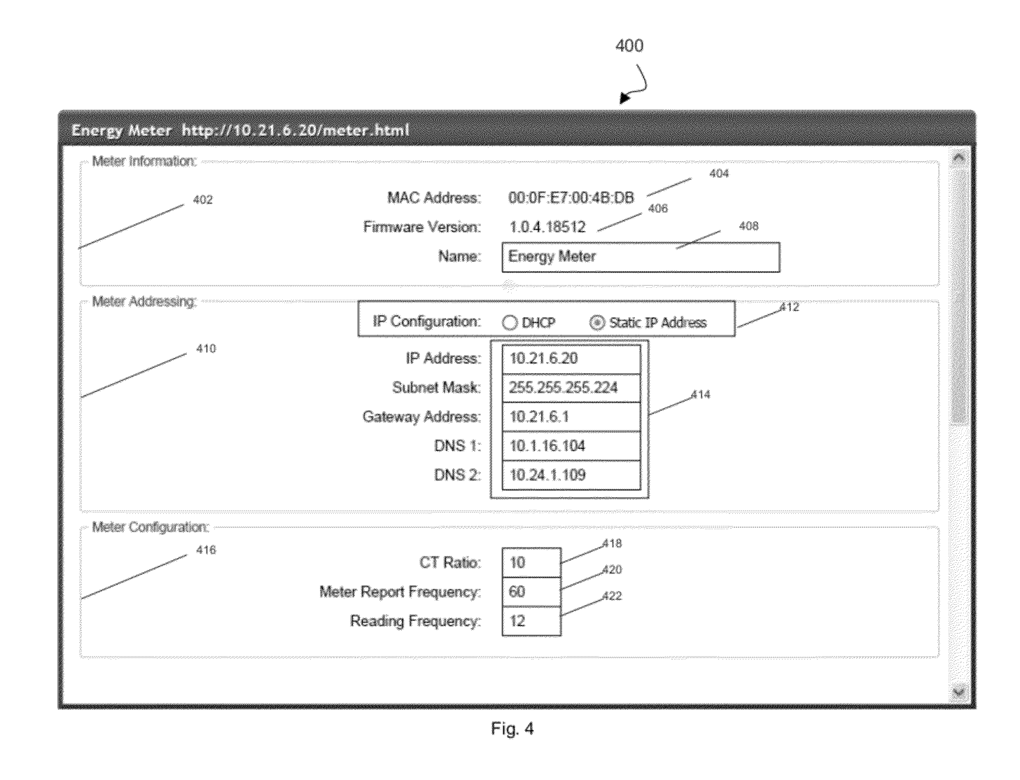

After the user submits proper authorization information, the user's browser software application is directed to the energy meter access display screen 300, such as shown in FIG. 3. Display screen 300 may be provided by the energy meter 142 or, alternatively, may be provided via a server device, such as the project server computing device 150. Information is preferably displayed in display screen 300, including the energy meter MAC Address 302, the energy meter name 304, the firmware version 306, and the current date/time 308. Information representing the local time zone and daylight saving time where the energy meter 142 is located is referenced and displayed in display screen 300. Moreover, graphical screen controls, such as button controls, are preferably provided for the user to make selections, including for Setup 310, Testing 312, and View Data 314. In an embodiment, selection of the Setup button 310 directs the user's browser software application to web page display screens, such as example screens 400, 500 and 600, illustrated in FIGS. 4-6, that include controls for configuring the energy meter 142.

Referring now to the example display screen 400 shown in FIG. 4, Meter Information section 402 includes information that represents the energy meter 142, such as the energy meter's 142 MAC Address 404, and preferably provided in a non-changing field and displayed from the energy meter's 142 firmware. Other information includes the energy meter firmware version 406, and the meter's 142 name 408, which is preferably a string of 50 characters or less, and formatted as Unicode Transformation Format (“UTF”). Information provided in display screens is preferably stored in one or more databases.

Continuing with reference to FIG. 4, Meter Addressing section 410 includes information representing the energy meter's 142 MAC address in the meter addressing section 410, and includes internet protocol (“IP”) Configuration 412, which may be configured via radio buttons for selection of Dynamic Host Configuration Protocol (“DHCP”) or a Static IP Address. If Static IP Address is selected, options 414 are provided for defining the energy meter's 142 network configuration, including IP Address, Subnet Mask, Gateway Address, Domain Name Server (“DNS”) 1 and DNS 2. Continuing with reference to FIG. 4, meter configuration 416 section is provided and includes current transformer (“CT”) Ratio 418, which represents a ratio between the primary and secondary sides of the current transformer, and is used by the energy meter 142 to measure current. Further, Meter Report Frequency 420 is provided that represents an amount of time, measured in minutes, between the energy meter 142 connections to the project server computing device 150 to report power usage and/or energy consumption.

In the example hardware arrangement illustrated in FIG. 1, a single energy meter 142 is illustrated to represent an installation in one facility. One skilled in the art will recognize that thousands of facilities may provide hardware installations that include energy meters 142. If each energy meter 142 in thousands of installations were to attempt to connect to the project server computing device 150 to report energy data at the same time, the project server computing device 150 may be overwhelmed by network traffic. In an embodiment, load balancing (i.e., network traffic management) on the project server computing device 150 is implemented by causing each respective energy meter 142 to report energy data after a predefined reporting interval.

In an embodiment, each of a plurality of energy meters 142 report energy information to the project server computing device 150 once per hour (e.g., per the Meter Report Frequency 420). In order to prevent hundreds or more energy meters 142 from reporting energy data to the project server computing device 150 at exactly the same time, an offset value may be used by each respective energy meter 142 to calculate a predefined amount of time, such as a number of seconds, to wait after a predefined reporting interval before energy meters 142 attempt to connect to the project server computing device 150. In an embodiment, each meter is assigned one of 256 possible offset values, which will effectively be used to reduce the volume of Internet traffic reporting energy data to a far more manageable degree, such as roughly 4 transactions per second during peak demand.

As used herein, the term “Report Time” refers, generally, to the amount of time in minutes after the hour when the energy meter 142 reports energy data to the project server computing device 150. The term “Offset Time” refers, generally, to the amount of time, in seconds, when the energy meter 142 will wait after the Report Time to connect to the project server computer device 150 to send energy data. As noted above, one purpose of Offset Time is to reduce the number of energy meters 142 that are connecting to the project server computing device 150 at any given moment.

Additionally, Reading Frequency 422 is provided, in minutes, and represents an amount of time between stored measurements and represents the frequency per hour at which the energy meter 142 will record data. Preferably, values evenly divide into 60 minutes (i.e., one-hour increment), and include: 1, 2, 3, 5, 6, 10, 12, 15, 20, 30, and 60. In the example shown in FIG. 4, the reading frequency is defined at 12 minutes. In this example, the energy meter 142 will take five readings (once every 12 minutes) over the course of an hour.

Thus, in an embodiment the energy meters 142 record data at specified intervals within a reporting period (such as 60 minutes). In an embodiment, each respective energy meter 142 uses the fifth byte of the meter's 142 MAC Address 404 to determine the Report Time, and the meter uses the sixth byte of the MAC address to determine the Offset Time. A calculation of the Report Time plus the Offset Time determines when the meter actually connects to the project server computing device 142 and transmits information.

For example, an energy meter's 142 Report Time can be determined from the value of the fifth byte of the MAC address, modulo the number of intervals. For an energy meter 142 having an address 00:40:9 D:31:F3:8 F, the fifth byte is 0xF3 (hexadecimal), or 243 (decimal). If the meter is configured for 5 intervals per hour the Report Time is 243% 5, which is 3. Thus, the meter's Report Time is the start of Interval is 3, which is thirty-six minutes after the hour.

Further, an energy meter's 142 Offset Time may be N seconds, where N is the sixth byte of the MAC address. For example, an energy meter 142 having a MAC address of 00:40:9 D:31:F3:8 F, the sixth byte is 0x8F (hexadecimal), or 143 (decimal). Thus, for example, at 1:00 a.m., the Report Time is 1:36:00, the Offset Time is 143 seconds or 0:02:23, and the energy meter 142 connects to the project server computing device 150 at 1:38:23. In another example, an energy meter 142 being configured for 5 intervals per hour and having a MAC address of 00:40:9 D:36:B4:C7 (again, at 1:00 am): the Report Time is 1:00:00, the Offset Time is 0:03:19, and thus, the energy meter 142 connects at 1:03:19.

Moreover, the energy meter 142 preferably stores the last 1024 records in a suitable memory, such as a circular buffer, as known in the art. For example, if the value in the Reading Frequency 422 control is 2, then the energy meter 142 stores the data for the last 2048 minutes.

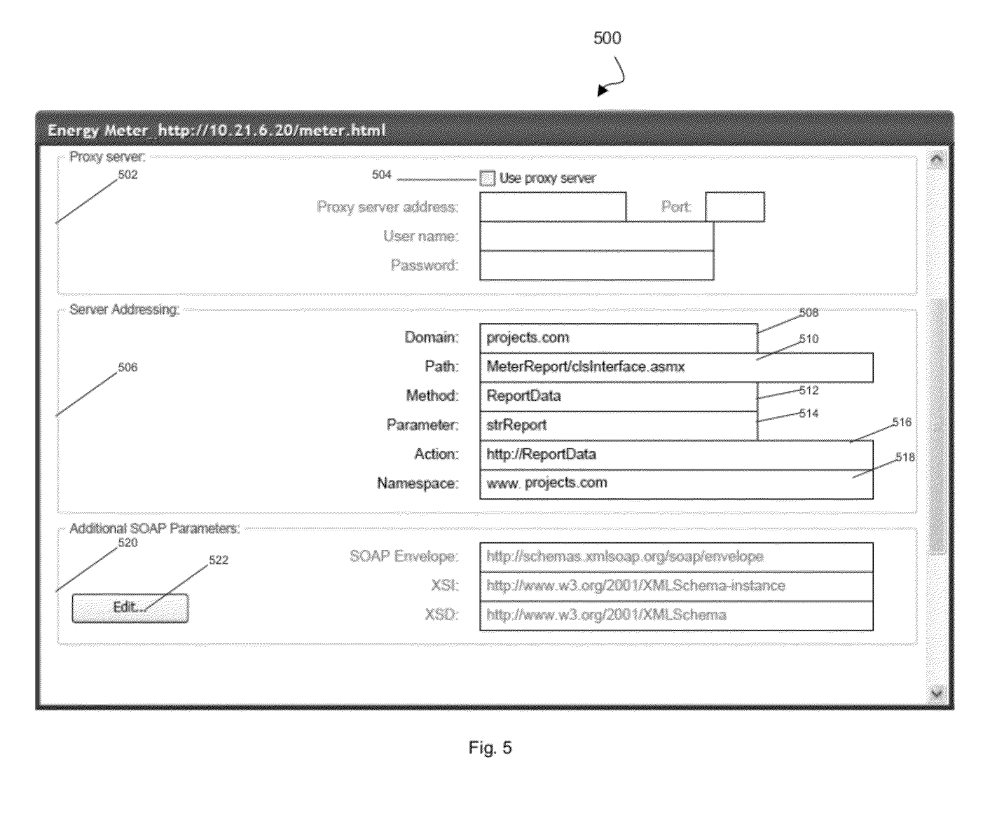

FIG. 5 illustrates a continued example display screen 500 provided in connection with configuring the energy meter 142. FIG. 5 illustrates example network settings for a user to configure the energy meter 142 to send and receive information over a communication network, such as the Internet 156. In Proxy Server section 502, proxy server checkbox 504, when checked, enables the energy meter 142 to communicate using a specified proxy server, and additional options for entering a Proxy server address (e.g., an IP address), a port number (e.g., a communication port on a firewall), a user name (if, for example, the proxy server requires a user name) and a password (if, for example, the proxy server requires a password) for using the proxy server.

In the example shown in FIG. 5, the proxy server checkbox 504 is not selected, thereby rendering the Proxy server address, port, user name and password textboxes disabled. In case no proxy server is used, Server Addressing section 506 is provided for a user, in a preferred embodiment, to submit a Domain 508, Path 510, Method 512, Parameter 514, Action 516 and Namespace 518 to define extensible markup language (“XML”) Simple Object Access Protocol (“SOAP”) packet parameters for communication with the project server computing device 150. In Additional SOAP Parameters section 520, options for configuring a SOAP Envelope, XSI (for specifying schema instance) and XSD (for specifying an XML Schema), can be edited to point to a different web service, as necessary or desired. If necessary, Additional Soap Parameters section 520 provides options that are preferably disabled, unless the user selects Edit button 522.

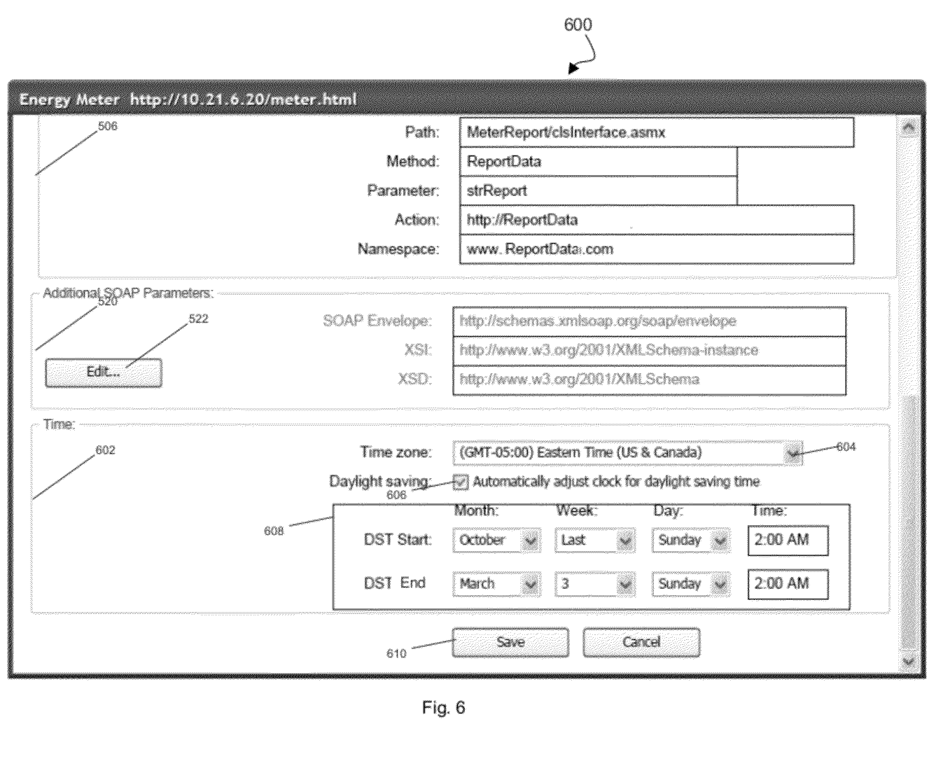

FIG. 6 illustrates an example display screen 600, which is continued from display screen 500, and provided in connection with configuring the energy meter 142. In the example shown in FIG. 6, Time section 602 provides options to enable the energy meter 142 to maintain time both in Greenwich Mean Time and in the energy meter's 142 local time. The options also enable the energy meter 142 to compensate for daylight saving time. In particular, Time Zone 604 provides a dropdown list of world time zones. Daylight savings checkbox 606, when checked, causes the energy meter 142 to observe daylight saving time, and the remaining fields in Time section 602 will be enabled. For example, daylight saving time (“DST”) section 608 includes DST Start options, including dropdown lists for a user to select a month, week, day and time when daylight saving time is scheduled to begin. Similarly, DST section 608 includes DST End, including dropdown lists for a user to select a month, week, day and time when daylight saving time is scheduled to end. Some implementations of daylight saving begin or end on a specified weekday of the month (e.g., first Sunday, third Sunday, etc.), or on the last weekday. If the value “last” is selected for the weekday, the system determines which week number in a given month when particular days fall. For example, the last Sunday would be the fourth weekday if there are four such weekdays, or the fifth if there are five. These options are useful, particularly in view of recent legislation that changed the dates when daylight saving time was scheduled to begin and end.

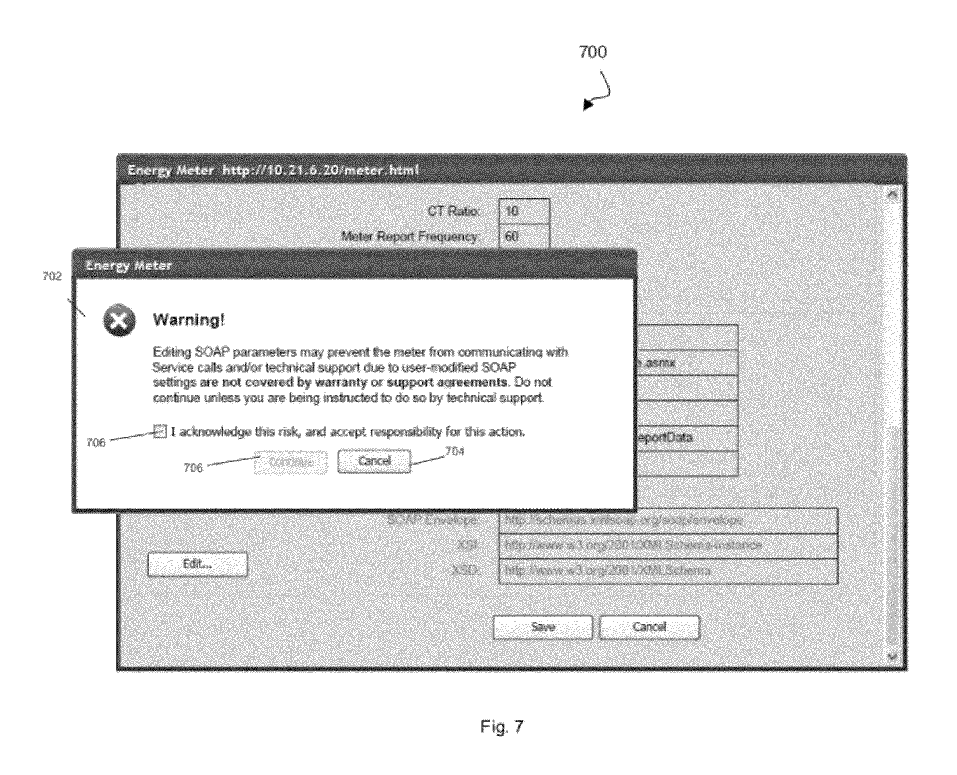

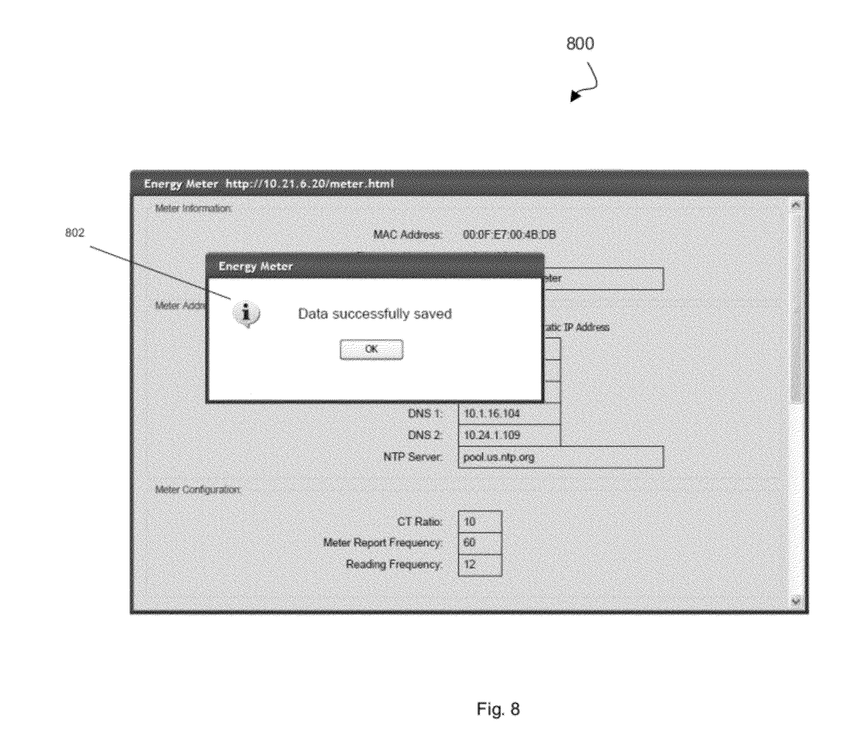

FIG. 7 illustrates an example display screen 700 provided in connection with configuring a meter 142, and representing a display warning when a user selects “Additional SOAP Parameters section 520 (FIG. 5). Modifying SOAP parameters is, typically, beyond the skill level of most users and in case the user selects Edit button 522 in the “Additional SOAP Parameters” section 520, the user is preferably presented with an alert 702, such as shown in FIG. 7. Cancel button 704 is provided for the user to close the alert 702 without taking any further action. Moreover, in the example shown in FIG. 7, Continue button 706 is provided in a disabled format, and can be enabled when the user selects “I acknowledge this risk, and take responsibility for this action” or other labeled checkbox 708. After the user selects Continue button 706, the alert 702 disappears, and the data entry controls for the SOAP Envelope, XSI and XSD values are enabled for entry. When the user selects Save button 610 (FIG. 6), a confirmation message 802 that data have been successfully is preferably displayed to the user (FIG. 8). saved the energy meter 142 preferably updates its database and, in case of a change to the database is reflected, the energy meter 142 may re-start and a dialog box or other display screen is preferably provided to warn the user that the energy meter 142 is going to reboot.

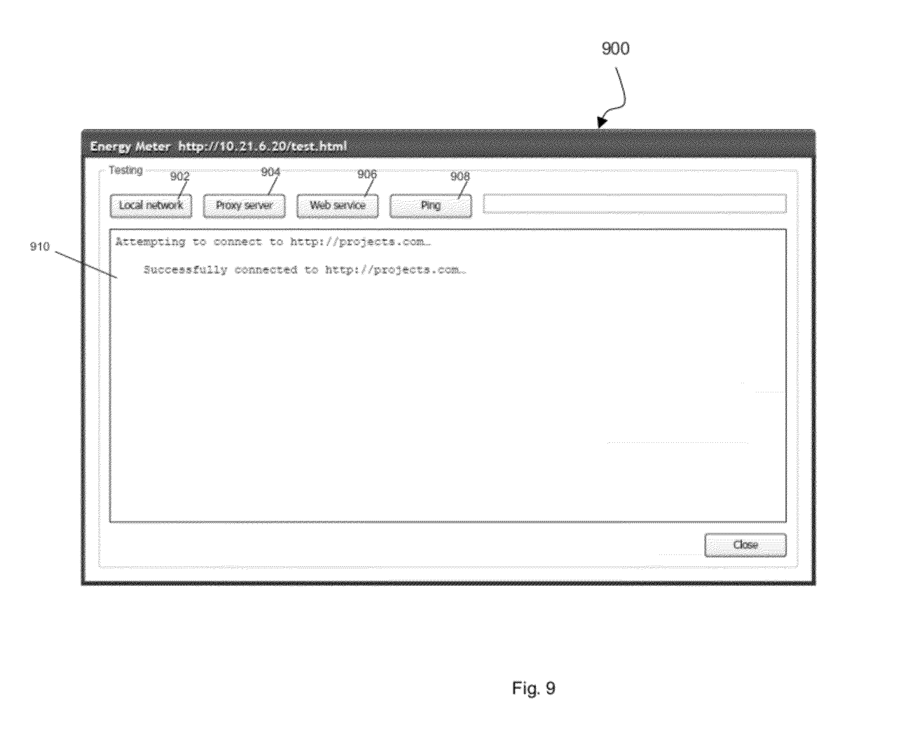

Continuing with the embodiment shown and described in connection with FIG. 3, selecting Testing button 312 preferably directs the user's browser software to a web page for testing various network connections. FIG. 9 illustrates an example network connection test display screen 900 that provides the user with the ability to perform various test functions. For example, Local network button 902, when selected, preferably tests connectivity to local network resources, such as described above. For example, selecting button 902 causes the energy meter 142 to ping the gateway address, resolve the address to settings defined above, and connect to an external web site (e.g., www.google.com). The test results indicate whether the test was successful.

Continuing with reference to FIG. 9, Proxy Server button 904 is enabled when the user specifies via Proxy Server section 502 (FIG. 5). When selected, Proxy Server button 904 causes the user's web browser software to transmit a request, such as an HTTP request, to the project server computing device 150 via the proxy server specified in Proxy Server section 502. Preferably, the results of the request are displayed, such as whether the request was successfully passed to the project server computing device 150. In one embodiment, use of Proxy Server button 904 is useful to determine whether the specified proxy server in Proxy Server section 502 requires the user to submit separate or additional authentication information, such as a user name and password. If so, then in an embodiment, once entered as a function of Proxy Server button 904, the information is stored for future use, thereby precluding a need for the user to repeatedly enter the separate or additional authentication information to the proxy server each time the user passes information to the project server computing device 150.

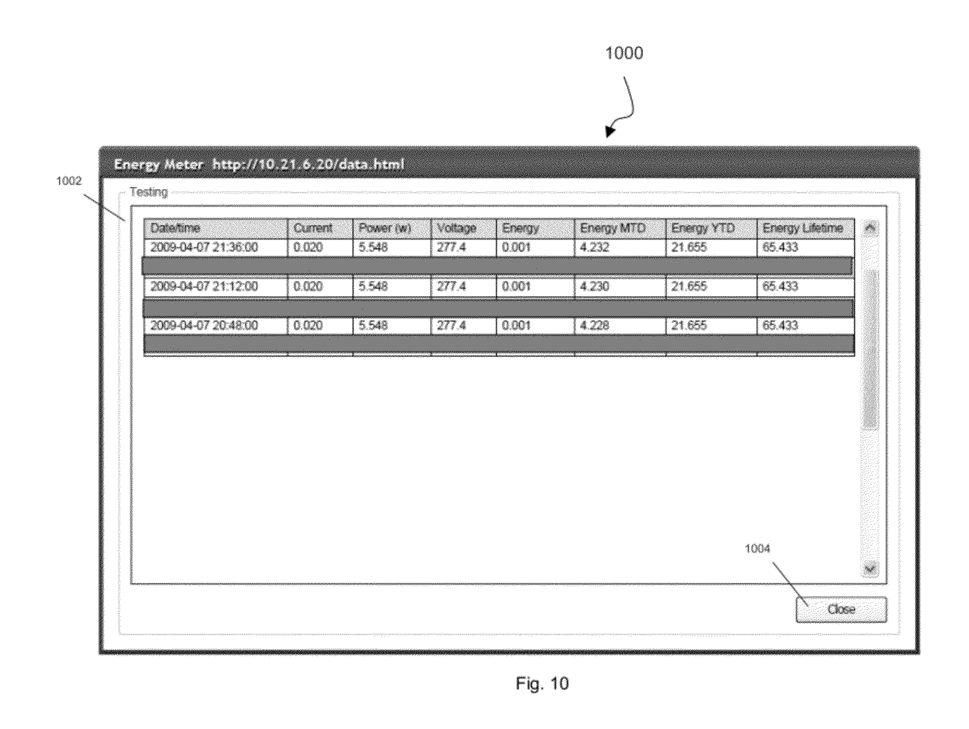

Continuing with reference to FIG. 9, Web Service button 906 is provided to send a test message to a specified web service to ensure proper functionality and connectivity of the service, as well as to display a message in a dialog box or other display indicating the results of the test. Ping button 908 preferably performs a PING, as known in the art, and the energy meter 142 displays records from the circular buffer (FIG. 10), and preferably sorted in descending order with the most recent value at the top.

In the embodiment and example illustrated in FIG. 10, table 1002 provides results of the testing, and is formatted such that the header row is tinted and every other row is similarly tinted for the display to be easy to read. In the example shown in FIG. 10, each row represents the outcome of tests at respective times. In the table, electric current is shown in amps (e.g., 0.020), power is shown in watts (e.g., 5.548), voltage is shown in volts (e.g., 277.4), and energy is shown in KWh (e.g., 0.001). As shown in FIG. 10, the value EnergyMTD (energy month to date) represents the total energy, measured in KWh, and which represents the sum of Energy measured at each reading since midnight on the first day of the month. EnergyYTD (energy year to date) represents the total energy, measured in KWh, and which represents the sum of Energy measured at each reading since midnight on the first day of the year. Energy Lifetime represents the total energy consumed since the energy meter 142 was initialized. Close button 1004 closes display screen 100 and may redirect the user back to the display screen 900, illustrated in FIG. 9.

One way that measurements and comparisons of a power usage and/or energy consumption savings between a digital lighting control system with a system that uses standard, prior art ballasts in accordance with teachings herein is by monitoring, measuring, and recording how dimming ballasts respond to photo sensors and the amount of energy that is saved, as a result. In one embodiment, the energy meter 142 records and reports power usage and/or energy consumption over a predetermined period of time, such as over a twelve-minute interval. After the energy meter 142 measures, the energy meter 142 generates or otherwise modifies a data file, and thereafter makes a connection, for example, via HTTP, to a computing device such as the project server computing device 150, and the energy meter 142 transmits the data thereto. In an embodiment, the data are formatted in a small file (e.g., 1,800 bytes) that is formatted in XML. In an alternative embodiment, a computing device, such as the project server computing device 150 and/or client computing device 152 establishes a connection with the energy meter 142 and polls the energy meter 142 either automatically or substantially automatically at a predefined frequency, (e.g., every 3 seconds). In this embodiment, the computing device polls the energy meter 142 without requiring user input to obtain power usage levels in near-real-time. In yet another alternative embodiment, a user of the computing device operates user interface controls to connect to the energy meter 142 “manually” and to obtain power usage and energy consumption information. Using the information received from the energy meter 142, a user can identify, for example, the impact of features of a digital addressable lighting control system, such as resulting from “daylighting,” as known in the art and described herein.

In an embodiment, the energy meter 142 is configured to use a dynamically allocated IP address, such as via DHCP, or, alternatively, to use a static IP address that does not change. In either case, the energy meter 142 preferably connects to one or more computing devices using HTTP web services. Moreover, the energy meter 142 preferably connects to the project server computing device 150 to maintain accuracy of the energy meter's 142 onboard real-time clock. In an alternative embodiment, the energy meter 142 may connect to a Simple Network Time Protocol (“SNTP”) server which may be “local” (e.g., behind the firewall 148), or a publicly available server, such as maintained by the U.S. Naval Observatory, outside the firewall 148.

In one or more installations of system 100, such as provided in a school district, it is preferred to configure the energy meter(s) 142 to use DHCP, and to program the energy meter(s) 142 to periodically connect to a server computer, such as project server computing device 150. In an embodiment, the MAC address of the energy meter 142 is displayed, such as on a physical label located on the outside panel of the energy meter 142, such that an information technology administrator can configure a permanent DHCP address lease and, if appropriate, to open a communications port (such as the well-known port 123) to enable outbound data packets to the project server computing device 150. Alternatively, data packets may be transmitted to a Network Time Protocol server 154 (FIG. 1), such as located at us.pool.ntp.org. This simplifies long term network maintenance in case, for example, a meter 142 addressing scheme changes, and reduces or precludes a need for re-programming energy meter 142. In an embodiment in which a static IP address is assigned to the energy meter 142, the meter's configuration information, such as described above with reference to Meter Addressing section 410 (FIG. 4), including IP address, subnet mask, first and second DNS servers, and a gateway address, will have to be re-entered and tested.

As noted herein, the energy meter 142 is preferably network accessible via standard web browsing software. For example, a teacher's desktop computer (e.g., client computing device 152) in a school is able to access the energy meter 142 using standard web browsing software, where the energy meter 142 is installed in an academic institution. The teacher can obtain near-real-time observation of energy consumption and/or power usage. In addition, the teacher may have access to one or more databases that store information relating to energy consumption and/or power usage over time for, for example, historical analyses and comparisons with departments, classrooms, facilities or other demarcated areas.

In addition to measuring power usage and savings, the present application promotes and provides for environmental awareness and education. The teachings herein provide an innovative way for teachers and educators to engage students in a meaningful conversation about environmental sustainability. For students, a unique opportunity is provided for positive change, and to witness the benefits of such change, as benefits relating to energy savings unfold. Moreover, in a classroom or similar location, one or more students and/or teachers can poll the energy meter 142 directly, as frequently as every few seconds, to view power levels substantially in real-time. This is particularly useful, for example, for showing the impact of daylighting, as shades are adjusted.

In a preferred embodiment, the energy meter 142 connects to project server computing device 150, and a message is transmitted by the energy meter 142 to the project server 150 upon occurrence of one or more events. Once the message is received, some corresponding activity occurs. For example, one event may be that the energy meter 142 has been instructed by the project server computing device 150 to request a firmware and/or bootloader software upgrade. Another event may be that the energy meter 142 executes instructions to determine whether it requires a firmware or bootloader update. In either case, the energy meter 142 initiates a process to update the firmware/and/or bootloader by sending a message to the server 150 that may be used to identify the firmware/bootloader versions that are available on the project server computing device 150 for download and installation. In an embodiment, the message enables the energy meter 142 to retrieve either firmware or bootloader code, but not both simultaneously. The energy meter 142 may also specify in the message which to retrieve (i.e., firmware or bootloader code), the respective version to retrieve and a range of line numbers. In this way, only particular lines in programming code may be added or replaced, thereby resulting in a shorter transfer and less involved upgrade process. In operation, the energy meter 142 sends a series of requests for specific lines at a scheduled time. The output includes records, and the energy meter 142 preferably performs a “checksum” or other integrity checking process to ensure that no errors occurred during transmission. Preferably, a checksum is performed for each line in the records, as well as the entire firmware image. Firmware records may include, for example, the energy meter 142's MAC address, minimum and maximum/line numbers, identifiers of specific line numbers and execution instructions.

During a request for updating the energy meter 142's firmware and/or a bootloader update, a message is sent to the meter 142 from a computing device, such as via software operating on a project computing device 150. The message preferably causes the energy meter 142 to immediately request a new firmware version from the project server computing device 150. In an embodiment, the message requests the firmware from a default URL, such as projects.sources.com, although the message may include, alternatively, a particular server address. In operation, the message may further include parameter values that instruct the energy meter 142 to get the firmware from default URL or from the specified local address. Other parameters may include instructions for sending an HTTP request, and a response to the message that includes no recognized exceptions indicates that the energy meter 142 has received the instruction(s), and will act accordingly, such as to request the project server computing device 150 for the latest firmware version.

In an embodiment, once per day the energy meter 142 sends a request to the project server computing device 150 for a firmware status to determine whether new firmware is available. Even though new firmware may be available, the project server computing device 150 may send a reply with an indication that no firmware update is scheduled or will be sent. Alternatively, the server may respond with data including specifics of a new version of firmware to download, as well as details indicating a time to download the firmware and other related information. For example, the message response to the energy meter 142 may include or be an XML file that includes the energy meter 142's MAC address, data tags identifying various features, such as described the above, including whether a firmware update and/or a bootloader update is available.

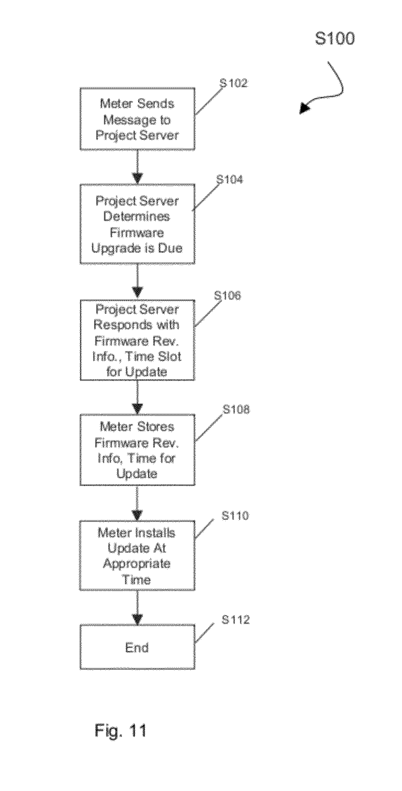

FIG. 11 illustrates example steps S100 associated with updating the firmware for an energy meter 142 according to an embodiment. At the start of a given day, the energy meter 142 sends a message to the project server computing device 150 that represents an inquiry whether a firmware and/or bootloader update is available or required (step S102). The project server 150 receives the message and references a database to determine whether an update is due (step S104). In case an update is due, then a message, such as in the form of a response to the message transmitted from the meter 142 is sent to the meter 142, with the current firmware version, as well as a predefined timeslot for installing the update (step S106). The energy meter 142 receives the update and stores the update in its memory until the appropriate time period per the predefined time period (step S108). At step S110, the meter installs the update, and at step S112, the process ends.

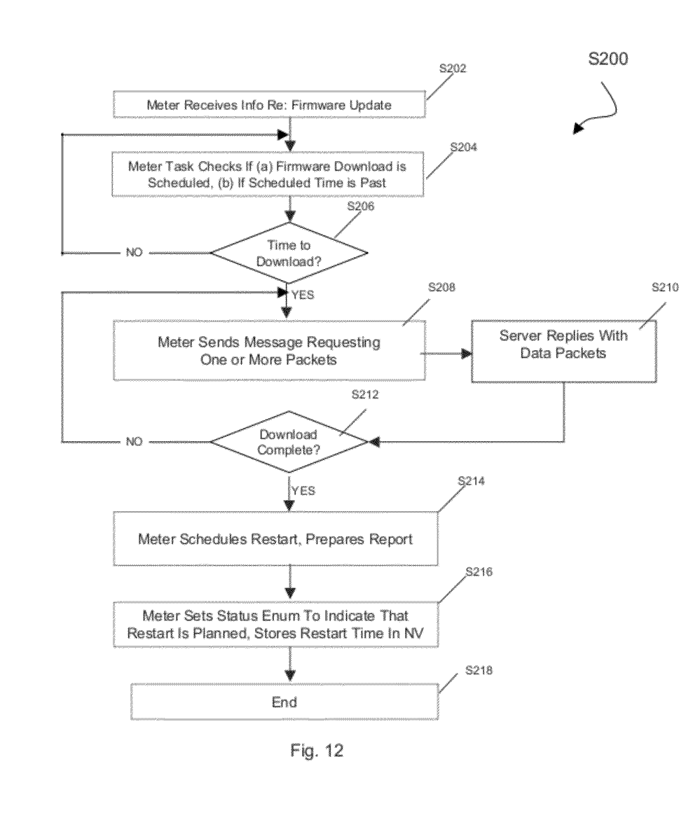

FIG. 12 illustrates example steps S200 associated with downloading an update to firmware for an energy meter 142 according to an embodiment. At step S202, the process starts, and at step S204, the energy meter 142 executes a task to determine whether a firmware download is scheduled and whether the scheduled time is past. At step S206, the task determines whether it is time to download the update. If not, then the process loops back to step S204. If, based on the determination at step S206, it is time to download, then the process branches to step S208 and the meter 142 transmits a message to the project server 150 requesting one or more packets of data comprised in the update. At step S210, the project server 150 replies and sends the appropriate data. At step S212, the meter 142 makes a determination whether the firmware download is complete and, if not then the process loops back to step S208 and the meter 142 requests additional data packets. Alternatively, when the download is complete, then the process branches to step S214 and the meter 142 schedules a time to restart itself to install the update, and prepares a report to be transmitted to the project server 150, accordingly. The meter sets a value to a variable (shown in FIG. 12 as “enum”) that represents to project server 150 that a restart of the meter 142 is planned, and the value is stored in a database (step S216). Thereafter the process ends (step S218).

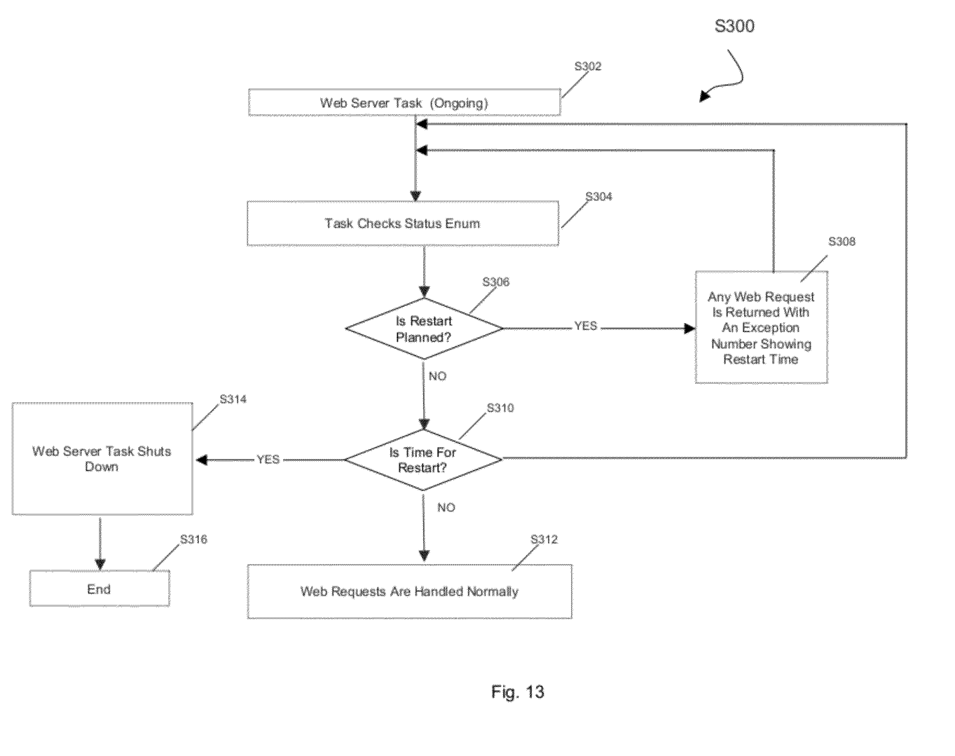

FIG. 13 illustrates example steps S300 associated with managing web services in connection with installing an update to firmware for an energy meter 142 according to an embodiment. At step 302, the process starts and web services are executed by the energy meter 142, such as to receive and send messages. At step S304, the energy meter 142 executes a task to check the value of the variable, “enum,” which was set in step S216 (FIG. 12). At step S306, the task determines whether an energy meter 142 restart is planned, for example, to install an update that was previously downloaded from project server 150. If so, then the process branches to step S308 and any web service request transmitted to the energy meter 142 is returned to the sender with an exception number that identifies the time when the restart is planned. Thereafter, the process continues to step S304. If, based on the determination in step S306 that no restart is planned, then the process branches to step S310 and a determination is made whether it is time for the meter 142 to restart and install the update. If the determination at step S310 indicates that it is not time for a restart, then the process branches to step S312, web services are handled normally. Alternatively, the process branches to step S314, and web services are terminated. Thereafter, the process ends at step S316.

It is recognized by the inventors that data representing energy savings and consumption requires very accurate timing and time synchronization. In a preferred embodiment, the teachings herein provide for time synchronization between devices to ensure that information representing power usage and savings is represented accurately. Thus, the energy meter 142 may require periodic synchronization, in one embodiment, with a SNTP server to maintain accuracy of the meter's onboard real time clock. Unfortunately, providing an accurate time creates an inherent dependency on the SNTP server, particularly during installation of the energy meter 142 at a customer site. The teachings herein eliminate or otherwise provide alternative solutions around this dependency.

In one embodiment, the energy meter 142 synchronizes its real-time clock (“RTC”) via calculating times associated with sending messages to and receiving responses thereto from the project server 150, which may be accomplished in a series of steps.

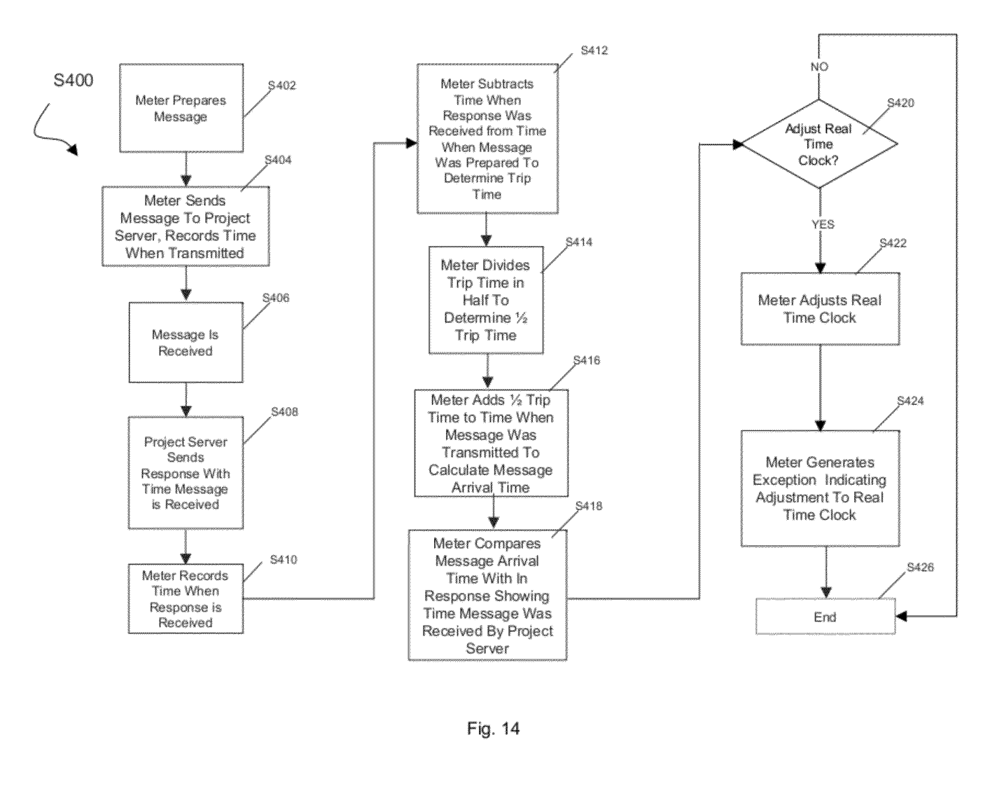

FIG. 14 is a flowchart illustrating example steps S400 associated with synchronizing a meter's 142 real time clock in accordance with an embodiment. At step S402, the energy meter 142 prepares a message that includes the energy meter 142's MAC address to be transmitted to the project server 150. The energy meter 142 transmits the message to the project server computing device 150 and the energy meter 142 records the time when the message is sent (i.e., SendTime) at step S404. At step S406, the project server computing device 150 receives the message. Thereafter, the project server 150 responds with a current time according to the energy meter 142's local time (i.e., LocalTime) which accounts for the energy meter 142's time zone, daylight saving time, and any other local characteristics at step S408. The energy meter 142 receives the message, and records the time when the response is received (i.e., ReceiveTime) at step S410. Preferably the energy meter 142 uses the elapsed time for the message's round-trip, and the local time value returned in the message, to compare with the existing time value stored in the energy meter 142's RTC.

Continuing with the example shown in FIG. 14, the energy meter 142 subtracts the time when the response was received (by the meter 142), from the time when the message was transmitted (by the meter 142) in order to calculate the time from when the message was sent to when the response was received (the “trip time”) (step S412). Thereafter, the energy meter 142 divides the trip time in half to determine the amount of time the message took to arrive at the project server 150 (the “½ trip time”) (step S414). The meter adds the calculated ½ trip time to the time when the message was transmitted to calculate the time when the message was received by the project server 150 (step S416). The energy meter 142 compares the calculated message arrival time with the time in the message indicating when the message was received by project server 150 (step S418). In other words, the energy meter 142 calculates the midpoint between the recorded SendTime and ReceiveTime, and compares it with the LocalTime value returned from the project server computing device 150.

At step S420, a determination is made whether the RTC requires an adjustment based on the comparison in step S418. Because the energy meter 142 has recorded the time when a message is sent and the time the message was received (i.e., the trip time), the energy meter 142 can evaluate the duration of the trip time in order to determine whether the RTC requires adjustment. The time interval value (i.e., the trip time) should be less than one second. If the time interval is greater than one second, then the RTC is not adjusted, and the process branches to step S426 and the process ends. If the RTC does require adjustment, then the process branches to step S422. For example, if the energy meter 142 time differs by more than a predetermined period of time, such as one second, the energy meter 142 adjusts the RTC by the difference. Further, the meter 142 records the time adjustment as an exception to indicate that the RTC was adjusted, and the exception is reported during the next message to the project server 150 (step S424). Thereafter, the process ends at step S426. Thus, an HTTP request that is sent with the energy meter 142 time is useable to compare the energy meter 142 time whenever the RTC adjustment exception is identified as a function of each message being time-stamped at the server.

In a preferred embodiment, load balancing is provided such that each meter 142 reports at respective period times, such as once per hour or other time period, and meters 142 will report at predetermined intervals. Preferably, the time period and/or the reporting interval are set as parameters, which are referenced by the energy meter 142. For example, 20% of all meters 142 report at:00, 20% report at:12, 20% at:24, and the like. In an alternative embodiment and to provide more explicit load balancing techniques, a respective offset value is applied for each meter 142, such that each meter 142 waits a predefined amount of time after its respectively defined reporting interval before attempting to communicate with the project server computing device 150 and to report power usage and/or energy consumption. In an embodiment, one of 256 unique offset values in one-byte. Preferably, meters 142 report data at specific intervals at particular report times that are represented in a number of minutes after a given hour. Moreover, meters 142 preferably wait an amount of time, termed herein as an “offset time,” that each meter 142 waits after the defined report time to attempt to connect to the project server computing device 150 and send data. Preferably, delaying attempts to connect to the project server computing device 150 after the report time by the offset time effectively reduces the number of meters 142 attempting to establish a communication session with the project server computing device 150.

In an embodiment, meters 142 record data at specified intervals within the reporting period. In an embodiment, the reporting period is sixty minutes, but may be another predefined amount of time. Moreover, the longer the length of intervals (e.g., in minutes), the fewer the number of intervals. For example, an interval defined for sixty minutes has only one interval. An interval length of 10 minutes, has six intervals. Moreover, a five minute interval length will have twelve intervals.

As noted above and in an embodiment, the energy meter 142 compensates for daylight saving time and, accordingly, is programmed with the current day, date, and time. In operation, the energy meter 142 determines whether the current day represents the start or end of daylight saving time by comparing the current day, time and/or date with the values that are provided by the user in section 602 (FIG. 6). In case the energy meter 142 determines that daylight saving time has begun, then at a designated time, the energy meter's 142 clock advances by one hour. Moreover, in an embodiment the energy meter 142 reports power usage and/or energy consumption in the hour prior to the daylight saving time advance, and in the hour after the programmed daylight saving time advance. The energy meter 142 records current, energy, volts and the like to be a value of zero in the circular buffer for records that would fall in the “missing” hour. For example, the value set for Reading Frequency 422 (FIG. 4) is 12 minutes, and the daylight saving time start in section 608 is configured to be 2:00 AM. Continuing with this example, the circular buffer contains five records for times 2:00, 2:12, 2:24, 2:36, 2:48. The energy meter 142 assigns a value of 0 for each record within those time periods, since once the clock springs forward, no power is actually used during that particular time period.

Similarly, in case the current day represents the end of daylight saving time, then at a designated time, the energy meter's 142 RTC retreats by one hour. For example, if the user configured in section 608 that the daylight saving time ends at 2:00 a.m., then the RTC “falls back” from 01:59:59 to 01:00:00. In an embodiment, the energy meter 142 maintains an internal value indicating that daylight saving time has ended, in order to prevent causing a condition, such as an infinite loop, whereby the energy meter 142 continually resets the clock meter 142 back by one hour when 2:00 a.m. is reached. Moreover, the amount of power usage and/or energy consumption for the hour (e.g. 01:00:00 to 01:59:59) has already been written to the circular buffer, since that time period has already occurred. Power usage and/or energy consumption for the following hour (i.e., the second period of time during 01:00:00 to 01:59:59) is combined with the reading for the next record (e.g. 02:12). Although there will appear to be a surge at 2:12 a.m. in power usage and/or energy consumption, the total value will be accurate. Continuing with meter 142 operations, each day the energy meter 142 determines whether the current day is the first day of a given month. If so, then the stored EnergyMTD value is preferably reset to a value of zero. In an embodiment, the previous EnergyMTD value is not stored “locally” at the energy meter 142 and the value is transmitted and stored in a database accessible by the project server computing device 150. Similarly, the energy meter 142 determines whether the current day is the first day of a given year. If so, then the stored EnergyYTD value is preferably reset to a value of zero. In an embodiment, the previous EnergyYTD value is not stored “locally” at the energy meter 142 and the value is transmitted and stored in a database accessible by the project server computing device 150. Moreover, the energy meter 142 preferably includes a self-updating procedure that enables the energy meter 142 to check for configuration updates (e.g. changes to SOAP parameters or reporting intervals) as well as for updated firmware each day (e.g., a “startofday” procedure). In an embodiment, the energy meter 142 checks for configuration updates by transmitting a message to the project server computing device 150 that requests updated configuration information.

Thus, as shown and described herein, power usage information is provided by the energy meter 142 that measures and reports power usage of at least one of a plurality of electrical loads that are connected into an electrical power network. The electric power meter is preferably synchronized to measure power usage at a particular time, and is further configured and operable to communicate over a first data network that is communicatively coupled to a second data network.

Moreover, the teachings herein provide a method for updating software that executes on the energy meter 142. The energy meter 142 preferably transmits a first request to the project computing device 150, wherein the request relates to whether a software update is due. In response, the energy meter 142 receives from the project server 150 at least one detail for updating the software. The energy meter 142 updates the software, accordingly.

Further, a graphical user interface is provided herein for configuring the energy meter 142, as well as to identify information regarding corresponding devices, such as project server 143 and project server 150.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

What is claimed is:

1. A method for providing power usage information by an electric power meter that measures and reports power usage of at least one of a plurality of electrical loads connected into an electrical power network, wherein the electric power meter is synchronized to measure power usage at a particular time, and is further configured and operable to communicate over a first data network that is communicatively coupled to a second data network, and further wherein at least one firewall is positioned between the first and second data networks, the method comprising:
synchronizing a real time clock provided with the electric power meter with a first computing device wherein the first computing device is provided with an accurate timestamp from outside the firewall;
reading, by the electric power meter, an amount of power used by the at least one load at a particular point in time; and
transmitting, by the electric power meter via a first communication session between the electric power meter and the first computing device, usage information that represents the amount of electricity used by the at least one load device at the particular point in time, wherein the particular point in time is accurately represented as a function of the synchronized real time clock.

2. The method of claim 1, wherein the usage information includes an identification of the meter.

3. The method of claim 1, wherein the meter receives power usage information from a current transformer on the electrical power network.

4. The method of claim 1, wherein the usage information is stored in a database.

5. The method of claim 1, further comprising synchronizing the real time clock by:
sending by the electric power meter a message to the first computing device;
recording, by the electric power meter, first time information from the real time clock representing a first time when the message is transmitted to the first computing device;
receiving, from the first computing device, a response to the message, wherein the response includes second time information representing a second time when the response to the message was transmitted from the first computing device to the electric power meter;
recording, by the electric power meter, third time information from the real time clock representing a third time when the response to the message is received by the electric power meter;
subtracting, by the electric power meter, the first time from the third time to determine a first calculated amount of time that represents an amount of time from when the message was sent from the electric power meter to when the response was received by the electric power meter;
dividing, by the electric power meter, the first calculated amount of time in half to determine a second calculated amount of time representing a transit time between the electric power meter and the first computing device;
adding, by the electric power meter, the second calculated amount of time to the first time to calculate a fourth time;
comparing the fourth time to the second time; and
synchronizing the real time clock based on the comparing.

6. The method of claim 5, wherein the synchronizing includes setting the time in the real time clock if the difference between the fourth time and the second time is more than a predetermined amount.

7. The method of claim 6, further comprising:
generating an alert when the electric power meter determines that the real time clock is to be adjusted based on the comparing; and
transmitting the alert from the electric power meter to the first computing device.

8. The method of claim 5, wherein the second time is local to the location of the electric power meter.

9. The method of claim 5, wherein the first computing device is located on the first data network, and further comprising synchronizing a first clock provided with the first computing device with a second clock provided with a second computing device located on the second data network, prior to synchronizing the real time clock provided with the electric power meter.

10. The method of claim 9, further comprising:
blocking a first port on the at least one firewall to prevent the meter from communicating with any computing device through the first port;
opening a second port on the at least one firewall to allow the first computing device to synchronize the clock provided with the first computing device.

11. The method of claim 1, further comprising calculating a time for transmitting the usage information.

12. The method of claim 11, wherein the calculating the time for transmitting the usage information includes:
determining a report time representing a first amount of time;
determining an offset time representing a second amount of time; and
adding the report time and the offset time to determine the time for transmitting the usage information.

13. The method of claim 12, wherein the determining the report time includes examining a respective byte of the electric power meter's media access control address.

14. The method of claim 12, wherein the determining the offset time includes examining a respective byte of the electric power meter's media access control address.

15. A method for updating software that executes on an electric power meter that measures and reports power usage of at least one of a plurality of electrical loads connected into an electrical power network, wherein the electric power meter is synchronized to measure power usage at a particular time, and is further configured and operable to communicate over a first data network that is communicatively coupled to a second data network, and further wherein at least one firewall is positioned between the first and second data networks, the method comprising:
transmitting by the electric power meter a first request to a first computing device, wherein the request relates to whether a software update is due;
receiving by the electric power meter a first response to the first request from the first computing device, wherein the first response includes at least one detail for updating the software; and
updating the software as a function of the at least one detail.

16. The method of claim 15, wherein the first request includes at least a first version identification that represents a version of the software that is installed on the electric power meter, and further wherein the at least one detail includes a second version identification of the software that represents another version of the software to be updated on the electric power meter, and yet further wherein the at least one detail includes a time for the electric power meter to download and update the software.

17. The method of claim 16, further comprising:
transmitting, by the electric power meter, a second request to the first computing device for at least one data packet substantially at the time included in the at least one detail;
receiving, from the first computing device and in response to the second request, the at least one data packet;
transmitting by the electric power meter a third request for at least one additional data packet;
receiving, from the first computing device and in response to the third request, the at least one additional data packet;
repeating the transmitting the third request and the receiving the at least one additional data packet until the software update is fully received by the electric power meter; and
installing the updated software in accordance with the at least one detail.

18. The method of claim 15, wherein the software is at least one of a bootloader and firmware.

19. A method for configuring an electric power meter that measures and reports power usage of at least one of a plurality of electrical loads connected into an electrical power network, wherein the electric power meter is synchronized to measure power usage at a particular time, and is further configured and operable to communicate over a first data network that is communicatively coupled to a second data network, and further wherein at least one firewall is positioned between the first and second data networks, the method comprising:
providing a graphical user interface via a first computing device over the second data network, wherein the graphical user interface provides controls for a user to configure the electric power meter to measure power usage at the particular time, and further to configure the electric power meter to request a software upgrade at predetermined time intervals.

20. The method of claim 19, wherein the graphical user interface further provides controls for the user to configure the electric power meter for at least one of:
machine access control address;
firmware version;
Dynamic Host Configuration Protocol;
static Internet protocol address;
current transformer ratio;
power reading frequency;
meter reporting frequency;
communicate via proxy server;
addressing information for the first computing device;
Simple Object Access Protocol configurations; and
time values relative to the electric power meter.

21. The method of claim 20, wherein the time values relative to the electric power meter include the time zone where the electric power meter is located, and settings for defining daylight saving time.

22. The method of claim 19, wherein the graphical user interface further includes controls for testing at least communication associated with the configured meter.

23. The method of claim 22, further comprising receiving a report from the first computing device in response to the testing that represents at least one of current usage, power usage, voltage usage, energy usage at one time, month to date energy usage, year to date energy usage, and energy usage of the life of the meter.

24. A system for updating software that executes on an electric power meter that measures and reports power usage of at least one of a plurality of electrical loads connected into an electrical power network, the system comprising:
a first data network;
a first computing device communicatively coupled to the first data network; and
the electric power meter, wherein the electric power meter is programmed and configured to:
transmit a first request over the first data network to the first computing device, wherein the request relates to whether a software update is due;
receive a first response to the first request from the first computing device, wherein the first response includes at least one detail for updating the software; and
update the software as a function of the at least one detail.

25. The system of claim 24, wherein the first request includes at least a first version identification that represents a version of the software that is installed on the electric power meter, and further wherein the at least one detail includes a second version identification of the software that represents another version of the software to be updated on the electric power meter, and yet further wherein the at least one detail includes a time for the electric power meter to download and update the software.

26. The system of claim 25, wherein the electric power meter is further programmed and configured to:
transmit a second request to the first computing device for at least one data packet substantially at the time included in the at least one detail;
receive, from the first computing device and in response to the second request, the at least one data packet;
transmit a third request for at least one additional data packet;
receive, from the first computing device and in response to the third request, the at least one additional data packet;
repeat the transmitting the third request and the receiving the at least one additional data packet until the software update is fully received by the electric power meter; and
install the updated software in accordance with the at least one detail.

27. The system of claim 24, wherein the software is at least one of a bootloader and firmware.

28. The system of claim 24, wherein the electric power meter is further programmed and configured to be synchronized to measure power usage at a particular time.

29. A system for configuring an electric power meter that measures and reports power usage of at least one of a plurality of electrical loads connected into an electrical power network, the system comprising:
a first data network;
the electric power meter, wherein the electric power meter is synchronized to measure power usage at a particular time;
a computing device that is communicatively coupled to the first data network and at least one other data network; and
a graphical user interface provided via the computing device that includes controls for configuring the electric power meter to measure power usage at the particular time, and further to configure the electric power meter to request a software upgrade at least one predetermined time interval.

30. The system of claim 29, wherein the graphical user interface further provides controls for configuring the electric power meter for at least one of:
machine access control address;
firmware version;
Dynamic Host Configuration Protocol;
static Internet protocol address;
current transformer ratio;
power reading frequency;
meter reporting frequency;
communicate via proxy server;
addressing information for the first computing device;
Simple Object Access Protocol configurations; and
time values relative to the electric power meter.

31. The system of claim 30, wherein the time values relative to the electric power meter include the time zone where the electric power meter is located, and settings for defining daylight saving time.

32. The system of claim 29, wherein the graphical user interface further includes controls for testing at least communication associated with the configured meter.

33. The system of claim 32, further comprising a report provided by the computing device in response to the testing, wherein the report represents at least one of current usage, power usage, voltage usage, energy usage at one time, month to date energy usage, year to date energy usage, and energy usage of the life of the meter.
